(19) United States
(12) Patent Application Publication
(10) Pub. No.: US 2022/0302818 A1
(43) Pub. Date: Sep. 22, 2022

(54) SEMICONDUCTOR POWER DEVICE AND SWITCHING POWER SUPPLY APPARATUS

(71) Applicant: SHARP KABUSHIKI KAISHA, Sakai City (JP)

(72) Inventor: YUKIO TAMAI, Sakai City (JP)

(21) Appl. No.: 17/697,532

(22) Filed: Mar. 17, 2022

(30) Foreign Application Priority Data
Mar. 17, 2021 (JP) 2021-043632

(51) Int. Cl. H02M 1/00; H02M 3/158; H03K 17/735

(52) U.S. Cl. CPC H02M 1/0051; H02M 3/158; H03K 17/735

(57) ABSTRACT

A current control element includes a control electrode, a first electrode, and a second electrode, is an element in which a current flowing from the second electrode to the first electrode is controlled by a voltage or a current between the control electrode and the first electrode, and does not include a built-in PN body diode between the first electrode and the second electrode, a rectifying element can be a Schottky barrier diode, a charge amount of the rectifying element at a time of reverse bias is smaller than an output charge amount of the current control element, an anode of the rectifying element and a cathode of the rectifying element are electrically connected to the auxiliary terminal and the second electrode, respectively, and the control electrode, the first electrode, and the second electrode are electrically connected to the control terminal, the first terminal, and the second terminal, respectively.

### CROSS-REFERENCE TO RELATED APPLICATION

The present application claims priority from Japanese Application JP2021-043632, the content to which is hereby incorporated by reference into this application.

### BACKGROUND OF THE INVENTION

### 1. Field of the Invention

One aspect of the present disclosure relates to a semiconductor power device.

In recent years, various proposals have been made regarding semiconductor power devices. For example, JP 2009-195054 discloses a power switching circuit that aims to reduce loss with a simple circuit configuration.

One aspect of the present disclosure is to realize a semiconductor power device having a lower loss and a smaller size than those of known ones.

In order to solve the problem described above, a semiconductor power device according to one aspect of the present disclosure includes a current control element and a rectifying element mounted in a same package, a control terminal, a first terminal, a second terminal, and an auxiliary terminal, each of the control terminal, the first terminal, the second terminal, and the auxiliary terminal being electrically connectable to an external circuit, wherein the current control element includes a control electrode, a first electrode, and a second electrode, the current control element is an element in which a current flowing from the second electrode to the first electrode is controlled by a voltage or a current between the control electrode and the first electrode, the current control element does not include a built-in PN body diode between the first electrode and the second electrode, the rectifying element is a Schottky barrier diode or a fast recovery diode, a charge amount of the rectifying element at a time of reverse bias is smaller than an output charge amount of the current control element, (i) an anode of the rectifying element and (ii) a cathode of the rectifying element are electrically connected to the auxiliary terminal and the second electrode, respectively, and (i) the control electrode, (ii) the first electrode, and (iii) the second electrode are electrically connected to the control terminal, the first terminal, and the second terminal, respectively.

A semiconductor power device according to one aspect of the present disclosure includes a current control element and a rectifying element mounted in a same package, a control terminal, a first terminal, a second terminal, and an auxiliary terminal, each of the control terminal, the first terminal, the second terminal, and the auxiliary terminal being electrically connectable to an external circuit, wherein the current control element includes a control electrode, a first electrode, and a second electrode, the current control element is an element in which a current flowing from the second electrode to the first electrode is controlled by a voltage or a current between the control electrode and the first electrode, the current control element does not include a built-in PN body diode between the first electrode and the second electrode, the rectifying element is a Schottky barrier diode or a fast recovery diode, a charge amount of the rectifying element at a time of reverse bias is smaller than an output charge amount of the current control element, (i) a cathode of the rectifying element and (ii) an anode of the rectifying element are electrically connected to the auxiliary terminal and the first electrode, respectively, and (i) the control electrode, (ii) the first electrode, and (iii) the second electrode are electrically connected to the control terminal, the first terminal, and the second terminal, respectively.

A semiconductor power device according to one aspect of the present disclosure includes a current control element, a first rectifying element, and a second rectifying element mounted in a same package, a control terminal, a first terminal, a second terminal, and an auxiliary terminal, each of the control terminal, the first terminal, the second terminal, and the auxiliary terminal being electrically connectable to an external circuit, wherein the current control element includes a control electrode, a first electrode, and a second electrode, the current control element is an element in which a current flowing from the second electrode to the first electrode is controlled by a voltage or a current between the control electrode and the first electrode, the current control element is formed of a wide gap semiconductor and includes a built-in PN body diode between the first electrode and the second electrode, the first rectifying element and the second rectifying element are rectifying elements different from the built-in PN body diode, each of the first rectifying element and the second rectifying element is a Schottky barrier diode or a fast recovery diode, a forward ON voltage of the first rectifying element and a forward ON voltage of the second rectifying element are smaller than a forward ON voltage of the built-in PN body diode, (i) an anode of the second rectifying element and (ii) a cathode of the second rectifying element are electrically connected to the first electrode of the current control element and the second electrode of the current control element, respectively, a charge amount of the first rectifying element at a time of reverse bias is smaller than a sum of an output charge amount of the current control element and a charge amount of the second rectifying element at a time of reverse bias, (i) an anode of the first rectifying element and (ii) a cathode of the first rectifying element are electrically connected to the auxiliary terminal and the second electrode, and (i) the control electrode, (ii) the first electrode, and (iii) the second electrode are electrically connected to the control terminal, the first terminal, and the second terminal, respectively.

A semiconductor power device according to one aspect of the present disclosure includes a current control element, a first rectifying element, and a second rectifying element mounted in a same package, a control terminal, a first terminal, a second terminal, and an auxiliary terminal, each of the control terminal, the first terminal, the second terminal, and the auxiliary terminal being electrically connectable to an external circuit, wherein the current control element includes a control electrode, a first electrode, and a second electrode, the current control element is an element in which a current flowing from the second electrode to the first electrode is controlled by a voltage or a current between the control electrode and the first electrode, the current control element is formed of a wide gap semiconductor and includes a built-in PN body diode between the first electrode and the second electrode, the first rectifying element and the second rectifying element are rectifying elements different from the built-in PN body diode, each of the first rectifying element and the second rectifying element is a Schottky barrier diode or a fast recovery diode, a forward ON voltage of the first rectifying element and a forward ON voltage of the second rectifying element are smaller than a forward ON voltage of the built-in PN body diode, (i) an anode of the second rectifying element and (ii) a cathode of the second rectifying element are electrically connected to the first electrode of the current control element and the second electrode of the current control element, respectively, a charge amount of the first rectifying element at a time of reverse bias is smaller than a sum of an output charge amount of the current control element and a charge amount of the second rectifying element at a time of reverse bias, (i) a cathode of the first rectifying element and (ii) an anode of the first rectifying element are electrically connected to the auxiliary terminal and the first electrode, and (i) the control electrode, (ii) the first electrode, and (iii) the second electrode are electrically connected to the control terminal, the first terminal, and the second terminal, respectively.

According to one aspect of the present disclosure a semiconductor power device having a lower loss and a smaller size than those of known ones can be realized.

### BRIEF DESCRIPTION OF THE DRAWINGS

FIG. 1 is a diagram illustrating a configuration of a main part of a semiconductor power device according to a first embodiment.

FIG. 2 is a diagram illustrating the semiconductor power device according to the first embodiment and a circuit configuration around the semiconductor power device.

FIG. 3 is a diagram illustrating a configuration of a main part of a semiconductor power device according to a second embodiment.

FIG. 4 is a diagram illustrating the semiconductor power device according to the second embodiment and a circuit configuration around the semiconductor power device.

FIG. 5 is a diagram illustrating a configuration of a main part of a semiconductor power device according to a third embodiment.

FIG. 6 is a diagram illustrating the semiconductor power device according to the third embodiment and a circuit configuration around the semiconductor power device.

FIG. 7 is a diagram illustrating a configuration of a main part of a semiconductor power device according to a fourth embodiment.

FIG. 8 is a diagram illustrating the semiconductor power device according to the fourth embodiment and a circuit configuration around the semiconductor power device.

FIG. 9 is a partial cross-sectional view of a semiconductor power device according to a fifth embodiment.

FIG. 10 is a diagram illustrating a configuration of a main part of the semiconductor power device according to the fifth embodiment.

FIG. 11 is a diagram illustrating a main circuit configuration of a switching power supply apparatus according to a sixth embodiment.

### DETAILED DESCRIPTION OF THE INVENTION

### First Embodiment

A semiconductor power device 1 of a first embodiment will be described below. Note that, for convenience of description, in each embodiment hereinafter, components having the same functions as those of components described in the first embodiment are denoted using the same reference numerals, and descriptions thereof will not be repeated. For the sake of simplicity, descriptions of similar items to known technologies are also omitted as appropriate.

Note that each configuration and each numerical value described in the present specification are merely examples unless otherwise specified. Accordingly, unless otherwise specified, a positional relationship of each member is not limited to an example of each drawing. Note that each drawing is for schematically describing a shape, a structure, and a positional relationship of each member, and is not necessarily drawn as in actual. In the present specification, a description “from A to B” regarding two numbers A and B means that “A or more and B or less” unless otherwise specified.

In the present specification, a description “connected” means that “electrically connected”, unless otherwise specified. Furthermore, in the present specification, for example, the control terminal TC is simply abbreviated as the TC as appropriate. Other members (components) are similarly abbreviated as appropriate.

### Configuration of Semiconductor Power Device 1

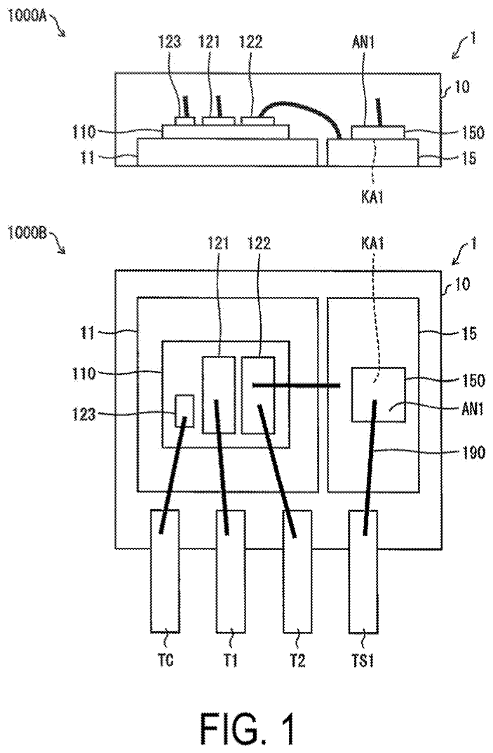

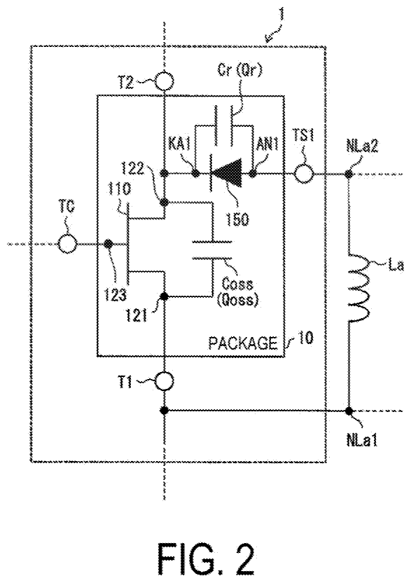

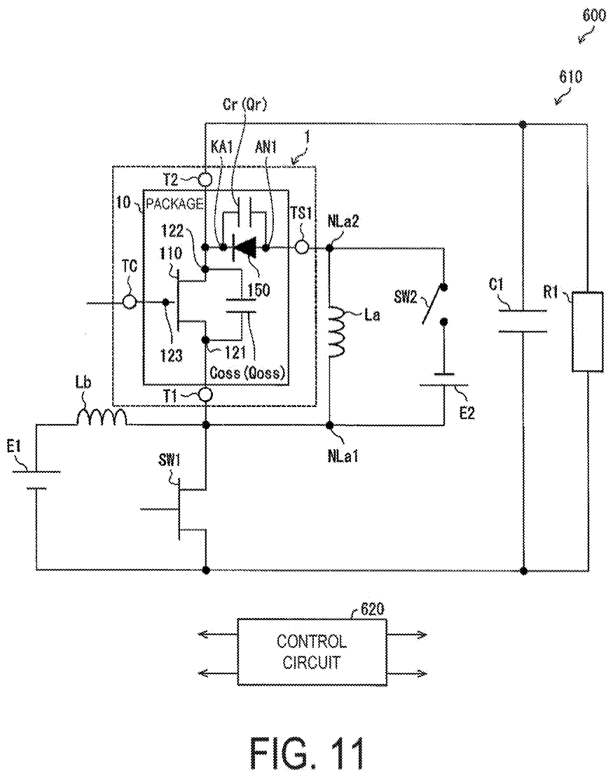

FIG. 1 is a diagram illustrating a configuration of a main part of a semiconductor power device 1. In FIG. 1, a reference numeral 1000A is a diagram schematically illustrating an internal structure of the semiconductor power device 1, and a reference numeral 1000B is a top view of the semiconductor power device 1. FIG. 2 is a diagram illustrating the semiconductor power device 1 and a circuit configuration around the semiconductor power device 1. An inductor La in FIG. 2 is an element in a main circuit 610 of a switching power supply apparatus 600 illustrated in FIG. 11 described later.

The semiconductor power device 1 includes a package 10, a first substrate 11, a second substrate 15, a current control element 110, a rectifying element 150, a control terminal TC, a first terminal T1, a second terminal T2, and an auxiliary terminal TS1. The first substrate 11 supports (holds) the current control element 110. The second substrate 15 supports the rectifying element 150. In the first embodiment, the first substrate 11 may be a conductive substrate (substrate having conductivity), or may be an insulating substrate (substrate having no conductivity). The second substrate 15 is a conductive substrate. Both the first substrate 11 and the second substrate 15 preferably have high thermal conductivity. The current control element 110 and the rectifying element 150 are mounted in the same (single) package 10.

The TC, the T1, the T2, and the TS1 are provided to protrude outside the package 10. Each of the TC, the T1, the T2, and the TS1 is a terminal connectable to an external circuit of the semiconductor power device 1 (see also FIG. 11). In the following description, the control terminal, the first terminal, the second terminal, and the auxiliary terminal are collectively referred to as external connection terminals. As an example, each of the external connection terminals may be connected to a corresponding part of the semiconductor power device 1 in the package 10 by a conductor wire 190. Also in the package 10, the parts of the semiconductor power device 1 may be connected to each other by the conductor wire 190. Alternatively, the parts of the semiconductor power device 1 may be connected to each other by a connection mechanism (not illustrated).

The current control element 110 includes a first electrode 121, a second electrode 122, and a control electrode 123. In the example of FIG. 1, the first electrode 121, the second electrode 122, and the control electrode 123 are provided on an upper surface of the current control element 110. The control electrode 123 is connected to the TC, the first electrode 121 is connected to the T1, and the second electrode 122 is connected to the T2. As a result, the current control element 110 is connected to the external circuit via the TC, the T1, and the T2.

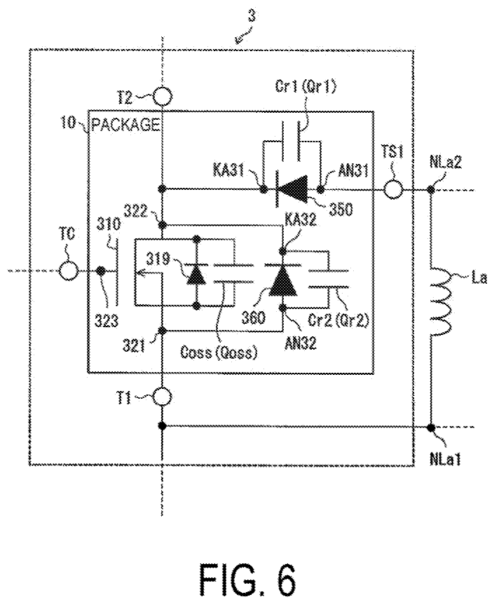

The current control element 110 is an element (semiconductor switching element) in which a current flowing from the second electrode 122 to the first electrode 121 is controlled by a voltage or a current between the control electrode 123 and the first electrode 121. The current control element 110 in the first embodiment does not include a built-in PN body diode between the first electrode and the second electrode, unlike a current control element 310 described later (see also FIG. 6 described later).

A typical example of the semiconductor switching element not including the built-in PN body diode between the first electrode and the second electrode may include a high electron mobility transistor (HEMT) and an insulated gate bipolar transistor (IGBT). Accordingly, the current control element 110 may be the HEMT or the IGBT. In FIG. 2, a voltage-driven type HEMT is illustrated as the current control element 110. Thus, as an example, the control electrode, the first electrode, and the second electrode according to one aspect of the present disclosure may be referred to as a gate electrode, a source electrode, and a drain electrode, respectively.

The rectifying element 150 includes an anode AN1 and a cathode KA1. The rectifying element 150 is a known diode. As described later, the rectifying element 150 is preferably a Schottky barrier diode (SBD) or a fast recovery diode (FRD). This also applies to each rectifying element described in each following embodiment. In the example of FIG. 1, the AN1 and the KA1 are provided on an upper surface and a lower surface of the rectifying element 150, respectively. As illustrated in FIG. 2, the AN1 is connected to the TS1, and the KA1 is connected to the T2.

In the present specification, a charge amount of a rectifying element (for example, the rectifying element 150) at a time of reverse bias is expressed as Qr. More strictly, the Qr means a charge amount charged (accumulated) in a depletion layer present between an anode and a cathode at the time of reverse bias of the rectifying element. In the example of FIG. 2, the depletion layer is equivalently represented by a capacitor Cr connected in parallel with the rectifying element 150. The Cr may be referred to as a parasitic capacitor of the rectifying element 150.

An output charge amount of a current control element (for example, the current control element 110) is expressed as Qoss. More precisely, the Qoss means a charge amount charged in the parasitic capacitor between the first electrode and the second electrode. In the example of FIG. 2, the parasitic capacitor is equivalently represented by a capacitor Coss connected in parallel with the current control element 110. In the following, for example, the capacitance of the Coss is also denoted by the Coss. In general, the Coss has non-linear properties depending on a potential difference between the first electrode and the second electrode. Specifically, as a potential of the second electrode with respect to the first electrode increases, the Coss decreases.

In FIG. 2, a path connected from the second electrode 122 to the rectifying element 150, the inductor La, and the T1 will be considered. Although the La exists in the path, it can be approximately regarded that the Cr is connected in parallel with the Coss. Accordingly, the Cr in the path causes an effect of effectively increasing the Coss. The increase of the Coss is a factor for increasing switching loss in a switching element SW1 (see FIG. 11) described later.

In the first embodiment, the switching loss in the SW1 can be reduced by a mechanism described later, by (i) intrinsic rectifying characteristics of the semiconductor power devices 1 realized by the elements except the Cr (parasitic capacitor of the rectifying element 150) and (ii) a function of the inductor La. However, as described above, when the effective Coss increases, the effect of reducing the loss due to the mechanism is reduced.

Thus, in order to effectively realize the loss reduction due to the mechanism described above, it is preferable to select the Cr and the Coss such that the Cr is smaller than the Coss. However, each of the Cr and the Coss has non-linear characteristics indicating a voltage dependence different from each other. Thus, as alternative measures for the Cr and the Coss, it is conceivable to use the respective charge amounts (Qr and Qoss) accumulated in the Cr and the Coss, in a case where the same voltage is applied to the Cr and the Coss. As is clear from the above description, in order to realize sufficient loss reduction effect due to the mechanism described above, it is preferable that the Qr be smaller than the Qoss. Thus, in the semiconductor power device 1, the current control element 110 and the rectifying element 150 are selected so that a relationship of Qr<Qoss is established (so that the Qr is smaller than the Qoss).

### Operation Example of Semiconductor Power Device 1

Semiconductor power device 1 is provided in, for example, a switching power supply circuit (for example, a step-up chopper circuit). Referring now to FIG. 11, an example of operation of the semiconductor power device 1 will be described. In the switching power supply, (i) the T1 or the T2 of the current control element 110 and (ii) the SW1 are connected in series with each other, and thus a half bridge is formed. In the switching power supply, the La is connected to nodes NLa1 and NLa2.

Here, in a state in which a bus voltage generated by a charge accumulated in the capacitor C1 is applied to the half bridge, a period (reverse conduction period) in which a reverse conductive current flows from the T1 to the T2 via the current control element 110 will be considered. In the switching power supply described above, a switching element SW2 is closed (tuned on) in the reverse conduction period in a circuit which is connected in parallel with the La and in which a power supply E2 and the SW2 are connected in series with each other, and thus a current ILa starts to flow though the La in a direction from the NLa1 to the NLa2. The current supplied from the E2 to the La is cut off by opening (turning off) the SW2 immediately before turning on the SW1.

Thus, a current (inductor current) that will continue to flow due to an energy accumulated in the La flows via the TS1 as a forward current of the rectifying element 150. The Coss is charged by the forward current, and the current control element 110 transitions to OFF.

The current flowing across the half bridge is reduced by an amount of the inductor current. Thus, the loss generated in the SW1 in a process of the SW1 transitioning from OFF to ON can be reduced.

A diode having a small reverse recovery time is preferably used as the rectifying element 150. Thus, in the first embodiment, the SBD or the FRD is used as the rectifying element 150. The SBD is known to be a diode having no injection of minority carriers and the reverse recovery time smaller than that of the FRD. Thus, the rectifying element 150 is particularly preferably the SBD.

### Effects of Semiconductor Power Device 1

As described above, according to the semiconductor power device 1, a semiconductor power device having a lower loss can be realized by a cooperative operation of the rectifying element 150 and the current control element 110. For example, the loss in the switching power supply provided with the semiconductor power device 1 can be reduced. However, in the related art (for example, JP 2009-195054 A), a specific relationship between the charge amount of the rectifying element (diode) at the time of reverse bias and the output charge amount of the current control element (semiconductor switching element) is not described. Thus, in JP 2009-195054 A, a specific configuration for realizing the cooperative operation between the rectifying element and the semiconductor switching element is not described. As described above, in the first embodiment, the lower loss of the semiconductor power device is realized based on new ideas different from those of the related art.

Furthermore, in the semiconductor power device 1, the current control element 110 and the rectifying element 150 are mounted in the same package 10. Thus, the semiconductor power device 1 can be reduced in size. As is clear from the above description, JP 2009-195054 A does not describe that the rectifying element and the semiconductor switching element operating in coordination with each other is mounted in the same package. As described above, according to the first embodiment, the semiconductor power device 1 having a lower loss and a smaller size than those of known ones can be realized.

### Second Embodiment

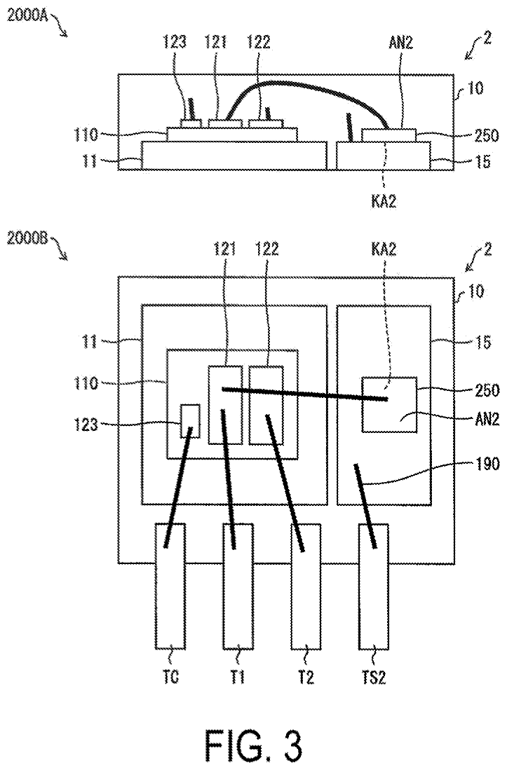

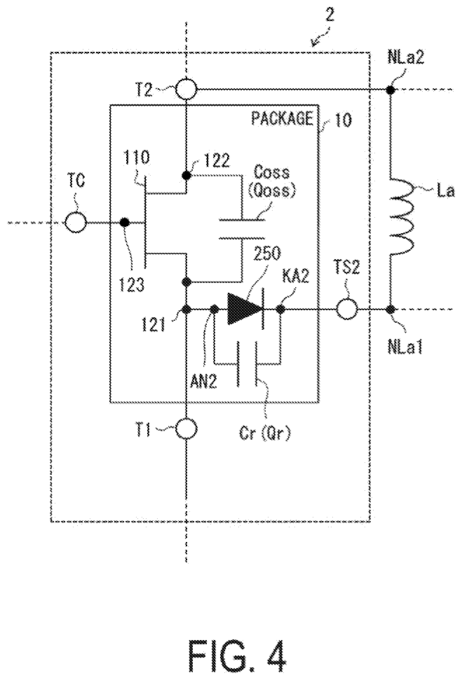

FIG. 3 is a diagram illustrating a configuration of a main part of a semiconductor power device 2 according to a second embodiment. In FIG. 3, a reference numeral 2000A is a diagram schematically illustrating an internal structure of the semiconductor power device 2, and a reference numeral 2000B is a top view of the semiconductor power device 2. FIG. 4 is a diagram illustrating the semiconductor power device 2 and a circuit configuration around the semiconductor power device 2.

An auxiliary terminal of the semiconductor power device 2 is referred to as an auxiliary terminal TS2. A rectifying element of the semiconductor power device 2 is referred to as a rectifying element 250. An anode and a cathode of the rectifying element 250 are referred to as an anode AN2 and a cathode KA2, respectively. In the example of FIG. 3, the AN2 and the KA2 are provided on an upper surface and a lower surface of the rectifying element 250, respectively.

Also in the semiconductor power device 2, similarly to the semiconductor power device 1, the rectifying element 250 and the current control element 110 are mounted in the same package 10. However, as illustrated in FIG. 4, in the semiconductor power device 2, the KA2 and the TS2 are connected to each other, and the AN2 and the first electrode 121 are connected to each other. Thus, in the second embodiment, the connection relationships of the anode and the cathode of the rectifying element are different from that of the first embodiment.

Also in the second embodiment, similarly to the first embodiment, the current control element 110 and the rectifying element 250 are selected so that a relationship of Qr<Qoss is established. Thus, as will be obvious to those skilled in the art, according to a connection relationship between the current control element 110 and the rectifying element 250 in the second embodiment, substantially similarly to the first embodiment, the rectifying element 250 and the current control element 110 can be cooperatively operated. Thus, the semiconductor power device 2 also can realize a semiconductor power device having a lower loss.

As described above, the semiconductor power device 2 also has similar effects to those of the semiconductor power device 1. As described above, the connection relationship of the rectifying element in the semiconductor power device according to one aspect of the present disclosure is not limited to the example of the first embodiment.

### Third Embodiment

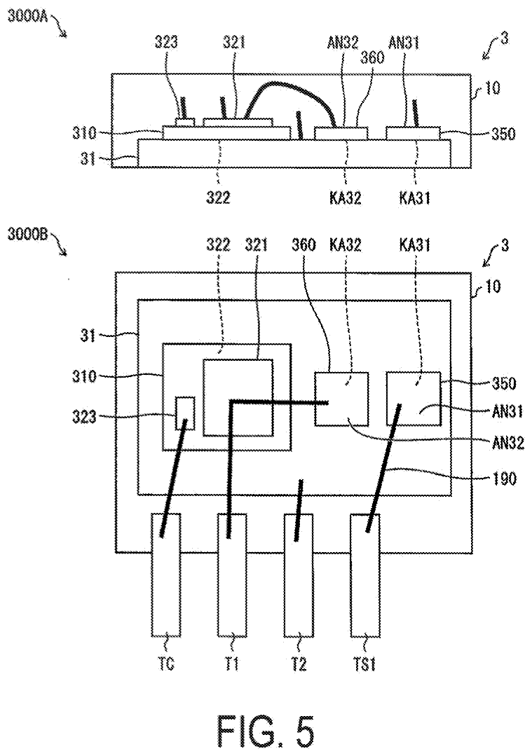

FIG. 5 is a diagram illustrating a configuration of a main part of a semiconductor power device 3 according to a third embodiment. In FIG. 5, a reference numeral 3000A is a diagram schematically illustrating an internal structure of the semiconductor power device 3, and a reference numeral 3000B is a top view of the semiconductor power device 3. FIG. 6 is a diagram illustrating the semiconductor power device 3 and a circuit configuration around the semiconductor power device 3.

The semiconductor power device 3 includes external connection terminals (TC to TS1) similar to those of the semiconductor power device 1. A current control element of the semiconductor power device 3 is referred to as a current control element 310. The semiconductor power device 3 includes a first rectifying element 350 and a second rectifying element 360. As described above, unlike the semiconductor power devices 1 and 2, the semiconductor power device 3 includes two rectifying elements. In the semiconductor power device 3, the current control element 310, the first rectifying element 350, and the second rectifying element 360 are mounted in the same package 10.

The semiconductor power device 3 includes a substrate 31. The substrate 31 supports the current control element 310, the first rectifying element 350, and the second rectifying element 360. As an example, the substrate 31 is a conductive substrate. As described above, unlike the semiconductor power devices 1 and 2, in the semiconductor power device 3, the current control element and the two rectifying elements are supported by the same substrate.

The current control element 310 is formed of a wide gap semiconductor. A first electrode, a second electrode, and a control electrode of the current control element 310 are referred to as a first electrode 321, a second electrode 322, and a control electrode 323, respectively. Unlike the semiconductor power devices 1 and 2, in the semiconductor power device 3, the second electrode 322 is provided on a lower surface of the current control element 310.

Similarly to the current control element 110, the current control element 310 is an element in which the current flowing from the second electrode to the first electrode is controlled by the voltage or the current between the control electrode and the first electrode. Connection relationships of the first electrode 321, the second electrode 322, and the control electrode 323 to the external connection terminals are similar to those of the current control element 110. The Qoss in the third embodiment represents an output charge amount of the current control element 310. The Coss in the example of FIG. 6 is connected to a built-in PN body diode 319 described below, in parallel.

The current control element 310 is formed of a wide gap semiconductor. Unlike the current control element 110, the current control element 310 additionally includes the built-in PN body diode between the first electrode and the second electrode. In the example of FIG. 6, the current control element 310 includes the built-in PN body diode 319 between the first electrode 321 and the second electrode 322. As is clear from FIG. 6, the built-in PN body diode 319 is an element different from the first rectifying element 350 and the second rectifying element 360.

A typical example of a semiconductor switching element including the built-in PN body diode between the first electrode and the second electrode includes a metal-oxide semiconductor field effect transistor (MOSFET) and a metal-insulator semiconductor FET (MISFET). Accordingly, the current control element 310 may be the MOSFET or the MISFET. In FIG. 6, a voltage-driven type MOSFET is illustrated as the current control element 310.

The first rectifying element 350 includes an anode AN31 and a cathode KA31. In the present specification, the anode (for example, AN31) of the first rectifying element is referred to as a first rectifying element anode. Similarly, the cathode (for example, KA31) of the first rectifying element is referred to as a first rectifying element cathode. In the example of FIG. 5, the AN31 and the KA31 are provided on an upper surface and a lower surface of the first rectifying element 350, respectively. As illustrated in FIG. 6, the AN31 is connected to the TS1, and the KA31 is connected to the second electrode 322.

The second rectifying element 360 includes an anode AN32 and a cathode KA32. In the present specification, the anode (for example, AN32) of the second rectifying element is referred to as a second rectifying element anode. Similarly, the cathode (for example, KA32) of the second rectifying element is referred to as a second rectifying element cathode. In the example of FIG. 5, the AN32 and the KA32 are provided on an upper surface and a lower surface of the second rectifying element 360, respectively. As illustrated in FIG. 6, the AN32 is connected to the first electrode 321, and the KA32 is connected to the second electrode 322.

In the present specification, (i) a charge amount of the first rectifying element (for example, the first rectifying element 350) at the time of reverse bias and (ii) a charge amount of the second rectifying element (for example, the second rectifying element 360) at the time of reverse bias is represented by Qr1 and Qr2, respectively. In the example of FIG. 6, a depletion layer present between the first rectifying element anode and the first rectifying element cathode is equivalently represented by a capacitor Cr1 connected in parallel with the first rectifying element 350. Similarly, the depletion layer present between the second rectifying element anode and the second rectifying element cathode is equivalently represented by a capacitor Cr2 connected in parallel with the second rectifying element 360.

In the present specification, (i) a forward ON voltage of the first rectifying element (for example, the first rectifying element 350), (ii) a forward ON voltage of the second rectifying element (for example, the second rectifying element 360), and (iii) a forward ON voltage of the built-in PN body diode (for example, the built-in PN body diode 319) are denoted by Von1, Von2, and Von3, respectively.

In a case where the current flows from the T1 to the T2 when the current control element 310 is in an OFF state, various current paths are conceivable. Here, in order to reduce the loss of the semiconductor power device 3, it is preferable to make the current passing through the built-in PN body diode 319 as small as possible. This is because there is a concern that a large loss due to the reverse recovery current may occur when a current passing through the built-in PN body diode 319 flows, since the built-in PN body diode 319 has a long reverse recovery time.

Thus, in order to make the current passing through the built-in PN body diode 319 as small as possible, in the semiconductor power device 3, the current control element 310, the first rectifying element 350, and the second rectifying element 360 are selected so that a relationship of “Von1, Von2<Von3” is established (so that Von1 and Von2 are smaller than Von3). By setting the Von1, the Von2, and the Von3 in this way, the large loss due to the reverse recovery current can be prevented from generating (turn on loss) in a switching element (for example, the SW1 in a circuit configuration in which the semiconductor power device 1 in the main circuit 610 is replaced with the semiconductor power device 3 in the example of FIG. 11) connected in series with the current control element 310.

Furthermore, in the semiconductor power device 3, based on similar concept to that of the first embodiment, the current control element 310, the first rectifying element 350, and the second rectifying element 360 are selected so that a relationship of “Qr1<Qoss+Qr2” is established (so that the Qr1 is smaller than the sum of the Qoss and the Qr2).

In the semiconductor power device 3, the second rectifying element 360 is connected in parallel with the current control element 310. Thus, the effective Qoss in the semiconductor power device 3 is expressed as Qoss+Qr2. In the semiconductor power device 3, a circuit in which the La and the first rectifying element 350 are connected in series with each other as a path in which a current flows for reducing switching loss is further connected in parallel with the current control element 310 and the second rectifying element 360. From the perspective of reducing loss, it is desirable that an ON-resistance of the first rectifying element 350 be small.

However, as is clear from the circuit configuration of FIG. 6, when the ON-resistance of the first rectifying element 350 is too small, the Qr1 is large. When the Qr1 is too large, there is a concern that an increase in loss exceeding the effect of reducing switching loss using the La described below will occur. Thus, it is preferable not to make the Qr1 too large. As described above, in the third embodiment, the Qr1 is set so that Qr1<Qoss+Qr2. By setting the Qr1 in this manner, sufficient loss reduction effect can be realized in the semiconductor power device 3.

### Operation Example of Semiconductor Power Device 3

Also in the switching power supply (for example, step-up chopper circuit) including the semiconductor power device 3, the current supplied from the E2 to the La is cut off by turning off the SW2 immediately before turning on the SW1.

In the third embodiment, a current (inductor current) that will continue to flow due to an energy accumulated in the La flows via the TS1 as a forward current of the first rectifying element 350. The Coss is charged by the forward current, and the current control element 310 transitions to OFF. In addition, the Cr2 is charged by the forward current.

Also in the third embodiment, similarly to the first embodiment, the current flowing across the half bridge is reduced by the amount of the inductor current. Thus, the loss generated in the SW1 in the process of the SW1 transitioning from OFF to ON can be reduced.

The first rectifying element 350 and the second rectifying element 360 are preferably the SBD or the FRD, for the same purpose as that of the rectifying element of the first embodiment. Furthermore, in the third embodiment, the reverse recovery time of the first rectifying element 350 (hereinafter referred to as a first reverse recovery time) and the reverse recovery time of the second rectifying element 360 (hereinafter referred to as a second reverse recovery time) are preferably substantially the same (almost the same). Accordingly, for example, the first rectifying element 350 and the second rectifying element 360 are preferably diodes of the same type. It is particularly preferable that both the first rectifying element 350 and the second rectifying element 360 be the SBDs.

In general, it is desirable that the first reverse recovery time and the second reverse recovery time be short. However, the second rectifying element 360 is connected in parallel with the first rectifying element 350 via the La. Thus, the effective reverse recovery time of the first rectifying element 350 and the second rectifying element 360 is defined by a longer one of the first reverse recovery time and the second reverse recovery time. Thus, as described above, in the semiconductor power device 3, it is preferable that the first reverse recovery time and the second reverse recovery time be set to be substantially the same. The first reverse recovery time and the second reverse recovery time are preferably 50 ns or less and more preferably 10 ns or less.

As an example, in the present specification, “the first reverse recovery time and the second reverse recovery time are substantially the same” means that “a difference between the first reverse recovery time and the second reverse recovery time is included within a relative error range of about ±20M”. Accordingly, for example, when the first reverse recovery time is 50 ns, the second reverse recovery time only needs to be approximately from 40 ns to 60 ns. Furthermore, when the first reverse recovery time is 10 ns, the second reverse recovery time only needs to be approximately from 8 ns to 12 ns.

As described above, according to the third embodiment, the first rectifying element 350, the second rectifying element 360, and the current control element 310 can be cooperatively operated. As a result, the semiconductor power device 3 also has similar effects to those of the semiconductor power device 1. As illustrated in the third embodiment, the semiconductor power device according to one aspect of the present disclosure may be realized by a combination of (i) the current control element including the built-in PN body diode and (ii) the two rectifying elements (the first rectifying element and the second rectifying element).

### Fourth Embodiment

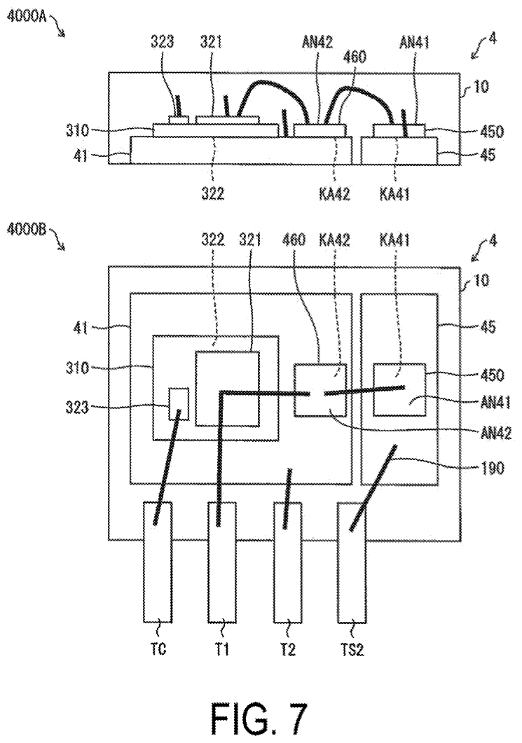

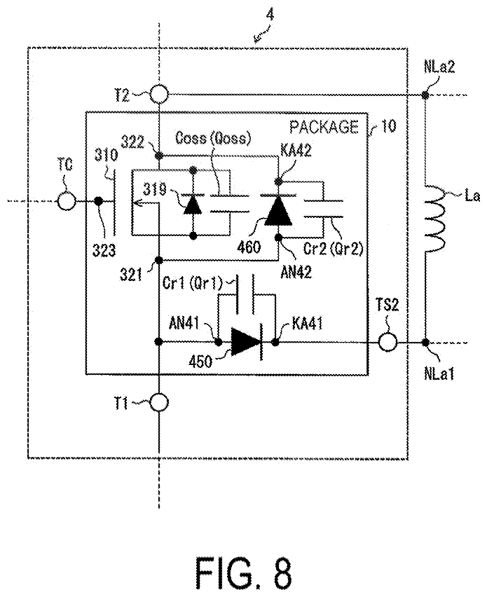

FIG. 7 is a diagram illustrating a configuration of a main part of a semiconductor power device 4 according to a fourth embodiment. In FIG. 7, a reference numeral 4000A is a diagram schematically illustrating an internal structure of the semiconductor power device 4, and a reference numeral 4000B is a top view of the semiconductor power device 4. FIG. 8 is a diagram illustrating the semiconductor power device 4 and a circuit configuration around the semiconductor power device 4.

The semiconductor power device 4 includes external connection terminals (TC to TS2) similar to those of the semiconductor power device 2. The first rectifying element and the second rectifying element of the semiconductor power device 4 are referred to as a first rectifying element 450 and a second rectifying element 460, respectively. The anode and the cathode of the first rectifying element 450 are referred to as an anode AN41 and a cathode KA41, respectively. The anode and the cathode of the second rectifying element 460 are referred to as an anode AN42 and a cathode KA42, respectively. In the example of FIG. 7, the AN41 and the KA41 are provided on an upper surface and a lower surface of the first rectifying element 450, respectively. Similarly, the AN42 and the KA42 are provided on an upper surface and a lower surface of the second rectifying element 460, respectively.

Also in the semiconductor power device 4, similarly to the semiconductor power device 3, the first rectifying element 450, the second rectifying element 460, and the current control element 310 are mounted in the same package 10. The semiconductor power device 4 includes a first substrate 41 and a second substrate 45. The first substrate 41 supports the current control element 310 and the second rectifying element 460. The second substrate 45 supports the first rectifying element 450. As an example, both the first substrate 41 and the second substrate 45 are conductive substrates.

As illustrated in FIG. 8, in the semiconductor power device 4, similar to the semiconductor power device 3, the AN42 and the first electrode 321 are connected to each other, and the KA42 and the second electrode 322 are connected to each other. However, in the semiconductor power device 4, the KA41 and the TS2 are connected to each other, and the AN41 and the first electrode 321 are connected to each other. Thus, in the semiconductor power device 4, a connection relationship between the anode and the cathode of the first rectifying element is different from that of the semiconductor power device 3.

Also in the fourth embodiment, the current control element 310, the first rectifying element 450, and the second rectifying element 460 are selected so that two relationships of “Von1, Von2<Von3” and “Qr1<Qoss+Qr2” are established.

Thus, as will be obvious to those skilled in the art, according to the connection relationship among the current control element 310, the first rectifying element 450, and the second rectifying element 460 in the semiconductor power device 4, substantially similarly to the third embodiment, the first rectifying element 450, the second rectifying element 460, and the current control element 310 can be operated cooperatively. Thus, the semiconductor power device 4 can also realize a semiconductor power device having a lower loss.

As described above, the semiconductor power device 4 also has similar effects to those of the semiconductor power device 3. As illustrated in the fourth embodiment, the connection relationship of the first rectifying element in the semiconductor power device according to one aspect of the present disclosure is not limited to the example of the third embodiment.

### Fifth Embodiment

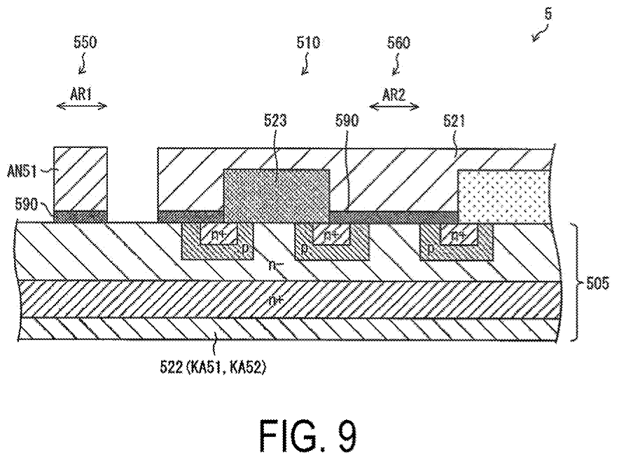

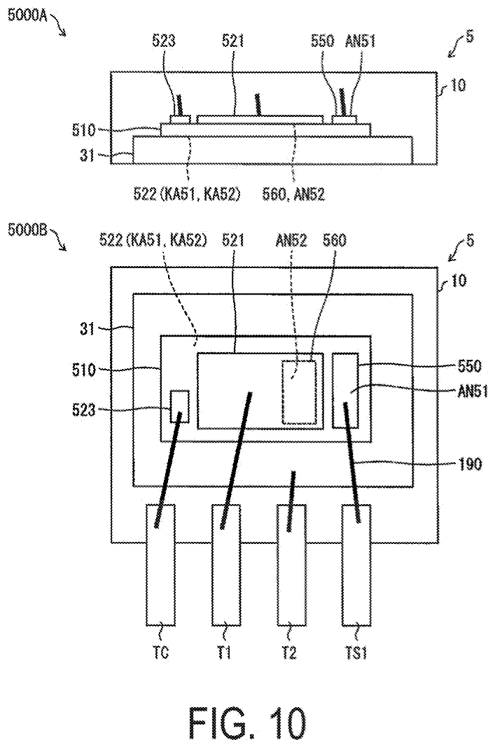

FIG. 9 is a partial cross-sectional view of a semiconductor power device 5 according to a fifth embodiment. FIG. 10 is a diagram illustrating a configuration of a main part of the semiconductor power device 5. In FIG. 10, a reference numeral 5000A is a diagram schematically illustrating an internal structure of the semiconductor power device 5, and a reference numeral 5000B is a top view of the semiconductor power device 5. Note that in FIG. 10, a semiconductor substrate 505 described below is not illustrated. A connection relationship of each part of the semiconductor power device 5 is similar to that of the semiconductor power device 3 (as illustrated in FIG. 6). Thus, the semiconductor power device 5 is a modified example of the semiconductor power device 3.

The current control element, the first rectifying element, and the second rectifying element of the semiconductor power device 5 are referred to as a current control element 510, a first rectifying element 550, and a second rectifying element 560, respectively. The first electrode, the second electrode, and the control electrode of the current control element 510 are referred to as a first electrode 521, a second electrode 522, and a control electrode 523, respectively. The anode and the cathode of the first rectifying element 550 are referred to as an anode AN51 and a cathode KA51, respectively. Similarly, the anode and the cathode of the second rectifying element 560 are referred to as an anode AN52 and a cathode KA52, respectively. In the semiconductor power device 5, the second electrode 522 is configured such that the second electrode 522 also serves as both the KA51 and the KA52.

As illustrated in FIG. 9, in the semiconductor power device 5, the current control element 510, the first rectifying element 550, and the second rectifying element 560 are formed at the same semiconductor substrate 505. In the example of FIG. 9, the first rectifying element 550 is formed in a first region AR1, and the second rectifying element 560 is formed in a second region AR2. The current control element 510 is formed in a region between the AR1 and the AR2. A metal layer 590 in FIG. 9 is provided in order to form the Schottky barrier in each of the first rectifying element 550 and the second rectifying element 560. As described above, the metal layer 590 may be referred to as a Schottky barrier forming metal layer.

As illustrated in the fifth embodiment, by forming the current control element, the first rectifying element, and the second rectifying element at the same semiconductor substrate (for example, the semiconductor substrate 505), the semiconductor power device can be further reduced in size. In addition, since a manufacturing process of the semiconductor power device can be facilitated, a manufacturing cost of the semiconductor power device can also be reduced.

### Sixth Embodiment

FIG. 11 is a diagram illustrating a main circuit configuration of a switching power supply apparatus 600 according to a sixth embodiment. The switching power supply apparatus 600 includes a main circuit 610 and a control circuit 620. The control circuit 620 controls each part of the main circuit 610. For example, the control circuit 620 switches ON/OFF of each switching element (for example, the current control element 110 and switching elements SW1 and SW2 described below) of the main circuit 610.

The main circuit 610 is, for example, a switching power supply circuit. The main circuit 610 in the example of FIG. 11 is a half bridge type step-up chopper circuit. The main circuit 610 includes a semiconductor power device (for example, the semiconductor power device 1) according to one aspect of the present disclosure, the power supplies E1 and E2, the inductors La and Lb, the switching elements SW1 and SW2, the capacitor C1, and a load R1. In the example of FIG. 11, the T1 is connected to the E1 (input side, low voltage side). The T2 is connected to the C1 and the R1 (output side, high voltage side). The TS1 is connected to the La. The TC is connected to the control circuit 620.

As described above, in the main circuit 610, a current can flow to an auxiliary terminal (for example, the TS1) of the semiconductor power devices via the La connected to the auxiliary terminal. Thus, the switching power supply apparatus 600 having a lower loss can be realized. Note that a transformer connected to the auxiliary terminal may be provided instead of the La. In this case, a current can flow to the auxiliary terminal via the transformer.

### SUPPLEMENTARY INFORMATION

An aspect of the present disclosure is not limited to each of the embodiments described above. It is possible to make various modifications within the scope indicated in the claims. An embodiment obtained by appropriately combining technical elements each disclosed in different embodiments also falls within the technical scope of an aspect of the present disclosure. Furthermore, technical elements disclosed in the respective embodiments may be combined to provide a new technical feature.

What is claimed is:

1. A semiconductor power device comprising:
a current control element and a rectifying element mounted in a same package;
a control terminal, a first terminal, a second terminal, and an auxiliary terminal, each of the control terminal, the first terminal, the second terminal, and the auxiliary terminal being electrically connectable to an external circuit,
wherein the current control element includes a control electrode, a first electrode, and a second electrode,
the current control element is an element in which a current flowing from the second electrode to the first electrode is controlled by a voltage or a current between the control electrode and the first electrode,
the current control element does not include a built-in PN body diode between the first electrode and the second electrode,
the rectifying element is a Schottky barrier diode or a fast recovery diode,
a charge amount of the rectifying element at a time of reverse bias is smaller than an output charge amount of the current control element,
(i) an anode of the rectifying element and (ii) a cathode of the rectifying element are electrically connected to the auxiliary terminal and the second electrode, respectively, and
(i) the control electrode, (ii) the first electrode, and (iii) the second electrode are electrically connected to the control terminal, the first terminal, and the second terminal, respectively.

2. The semiconductor power device according to claim 1,
wherein the current control element is an HEMT or an IGBT.

3. A semiconductor power device comprising:
a current control element and a rectifying element mounted in a same package;
a control terminal, a first terminal, a second terminal, and an auxiliary terminal, each of the control terminal, the first terminal, the second terminal, and the auxiliary terminal being electrically connectable to an external circuit,
wherein the current control element includes a control electrode, a first electrode, and a second electrode,
the current control element is an element in which a current flowing from the second electrode to the first electrode is controlled by a voltage or a current between the control electrode and the first electrode,
the current control element does not include a built-in PN body diode between the first electrode and the second electrode,
the rectifying element is a Schottky barrier diode or a fast recovery diode,
a charge amount of the rectifying element at a time of reverse bias is smaller than an output charge amount of the current control element,
(i) a cathode of the rectifying element and (ii) an anode of the rectifying element are electrically connected to the auxiliary terminal and the first electrode, respectively, and
(i) the control electrode, (ii) the first electrode, and (iii) the second electrode are electrically connected to the control terminal, the first terminal, and the second terminal, respectively.

4. The semiconductor power device according to claim 3,
wherein the current control element is an HEMT or an IGBT.

5. A semiconductor power device comprising:
a current control element, a first rectifying element, and a second rectifying element mounted in a same package;
a control terminal, a first terminal, a second terminal, and an auxiliary terminal, each of the control terminal, the first terminal, the second terminal, and the auxiliary terminal being electrically connectable to an external circuit,
wherein the current control element includes a control electrode, a first electrode, and a second electrode,
the current control element is an element in which a current flowing from the second electrode to the first electrode is controlled by a voltage or a current between the control electrode and the first electrode,
the current control element is formed of a wide gap semiconductor and includes a built-in PN body diode between the first electrode and the second electrode,
the first rectifying element and the second rectifying element are rectifying elements different from the built-in PN body diode,
each of the first rectifying element and the second rectifying element is a Schottky barrier diode or a fast recovery diode,
a forward ON voltage of the first rectifying element and a forward ON voltage of the second rectifying element are smaller than a forward ON voltage of the built-in PN body diode,
(i) an anode of the second rectifying element and (ii) a cathode of the second rectifying element are electrically connected to the first electrode of the current control element and the second electrode of the current control element, respectively,
a charge amount of the first rectifying element at a time of reverse bias is smaller than a sum of an output charge amount of the current control element and a charge amount of the second rectifying element at a time of reverse bias,
(i) an anode of the first rectifying element and (ii) a cathode of the first rectifying element are electrically connected to the auxiliary terminal and the second electrode, respectively, and
(i) the control electrode, (ii) the first electrode, and (iii) the second electrode are electrically connected to the control terminal, the first terminal, and the second terminal, respectively.

6. The semiconductor power device according to claim 5,
wherein the current control element, the first rectifying element, and the second rectifying element are formed at a same semiconductor substrate.

7. The semiconductor power device according to claim 5,
wherein a reverse recovery time of the first rectifying element and a reverse recovery time of the second rectifying element are substantially same.

8. The semiconductor power device according to claim 5,
wherein the current control element is an MOSFET or an MISFET.

9. A semiconductor power device comprising:
a current control element, a first rectifying element, and a second rectifying element mounted in a same package;
a control terminal, a first terminal, a second terminal, and an auxiliary terminal, each of the control terminal, the first terminal, the second terminal, and the auxiliary terminal being electrically connectable to an external circuit,
wherein the current control element includes a control electrode, a first electrode, and a second electrode,
the current control element is an element in which a current flowing from the second electrode to the first electrode is controlled by a voltage or a current between the control electrode and the first electrode,
the current control element is formed of a wide gap semiconductor and includes a built-in PN body diode between the first electrode and the second electrode,
the first rectifying element and the second rectifying element are rectifying elements different from the built-in PN body diode,
each of the first rectifying element and the second rectifying element is a Schottky barrier diode or a fast recovery diode,
a forward ON voltage of the first rectifying element and a forward ON voltage of the second rectifying element are smaller than a forward ON voltage of the built-in PN body diode,
(i) an anode of the second rectifying element and (ii) a cathode of the second rectifying element are electrically connected to the first electrode of the current control element and the second electrode of the current control element, respectively,
a charge amount of the first rectifying element at a time of reverse bias is smaller than a sum of an output charge amount of the current control element and a charge amount of the second rectifying element at a time of reverse bias,
(i) a cathode of the first rectifying element and (ii) an anode of the first rectifying element are electrically connected to the auxiliary terminal and the first electrode, and
(i) the control electrode, (ii) the first electrode, and (iii) the second electrode are electrically connected to the control terminal, the first terminal, and the second terminal, respectively.

10. The semiconductor power device according to claim 9,
wherein a reverse recovery time of the first rectifying element and a reverse recovery time of the second rectifying element are substantially same.

11. The semiconductor power device according to claim 9,
wherein the current control element is an MOSFET or an MISFET.

12. A switching power supply apparatus comprising:
the semiconductor power device according to claim 1; and
an inductor or a transformer electrically connected to the auxiliary terminal,
wherein a current flows to the auxiliary terminal via the inductor or the transformer.

13. A switching power supply apparatus comprising:
the semiconductor power device according to claim 3; and
an inductor or transformer electrically connected to the auxiliary terminal,
wherein a current flows to the auxiliary terminal via the inductor or the transformer.

14. A switching power supply apparatus comprising:
the semiconductor power device according to claim 5; and
an inductor or transformer electrically connected to the auxiliary terminal,
wherein a current flows to the auxiliary terminal via the inductor or the transformer.

15. A switching power supply apparatus comprising:
the semiconductor power device according to claim 9; and
an inductor or transformer electrically connected to the auxiliary terminal,
wherein a current flows to the auxiliary terminal via the inductor or the transformer.
